(19) United States
(12) Patent Application Publication
(10) Pub. No.: US 2025/0048881 A1
(43) Pub. Date: Feb. 6, 2025

(54) DISPLAY DEVICE

(71) Applicant: SAMSUNG DISPLAY CO., LTD., Yongin-si (KR)

(72) Inventor: Geun Woo YUG, Yongin-si (KR)

(21) Appl. No.: 18/607,678

(22) Filed: Mar. 18, 2024

(30) Foreign Application Priority Data
Aug. 3, 2023 (KR) 10-2023-0101479

(51) Int. Cl. H10K 59/80; H10K 102/00

(52) U.S. Cl. CPC H10K 59/80; H10K 2102/311

(57) ABSTRACT

A display device includes: a display panel including a folding area; and a panel support layer disposed on the display panel and including a folding portion that overlaps the folding area, wherein the panel support layer includes: one or more bars and one or more slits alternately arranged with each other in the folding portion; and a filler disposed at least partially in the one or more of slits, and wherein the filler is disposed in first row slits among the one or more slits that are located at two ends of the folding portion.

### CROSS-REFERENCE TO RELATED APPLICATION

This application claims priority under 35 U.S.C. § 119 to Korean Patent Application No. 10-2023-0101479, filed on Aug. 3, 2023, in the Korean Intellectual Property Office, the disclosure of which is incorporated by reference herein in its entirety.

### TECHNICAL FIELD

The present invention relates to a display device, and more particularly, to a display device including a panel support member.

### DISCUSSION OF THE RELATED ART

As the information-oriented society evolves and further develops, demand for further development of display devices increases. For example, display devices are being incorporated into a variety of electronic devices such as smart phones, digital cameras, laptop computers, navigation devices, and smart televisions.

Recently, to increase portability of the display device and provide a wider display screen, a bendable display device, in which the display area can be bent, or a foldable display device, in which the display area can be folded, is under development.

### SUMMARY

According to an embodiment of the present invention, a display device includes: a display panel including a folding area; and a panel support layer disposed on the display panel and including a folding portion that overlaps the folding area, wherein the panel support layer includes: one or more bars and one or more slits alternately arranged with each other in the folding portion; and a filler disposed at least partially in the one or more of slits, and wherein the filler is disposed in first row slits among the one or more slits that are located at two ends of the folding portion.

In an embodiment of the present invention, the filler is disposed only partially in the first row slits.

In an embodiment of the present invention, a length of the filler is smaller than a length of the first row slits.

In an embodiment of the present invention, the filler is disposed adjacent to an end of the folding portion.

In an embodiment of the present invention, ends of the filler are flat surfaces.

In an embodiment of the present invention, the ends of the filler and the end of the folding portion are positioned on substantially a same plane.

In an embodiment of the present invention, the end of the folding portion of the panel support layer protrudes beyond an end of the display panel.

In an embodiment of the present invention, the end of the folding portion includes a first region that protrudes beyond the end of the display panel, wherein the first row slits at least partially overlap with the first region, and wherein the filler is disposed only in the first region.

In an embodiment of the present invention, a length of the first region is equal to the length of the filler.

In an embodiment of the present invention, the filler is not disposed in row slits other than the first row slits.

In an embodiment of the present invention, a modulus of the filler is equal to or less than about 15 MPa.

In an embodiment of the present invention, the filler includes: first portions disposed in the first row slits; and a second portion disposed outside of the first row slits, and wherein the second portion overlaps the one or more slits and the one or more bars.

In an embodiment of the present invention, the second portion includes recesses that overlap with the one or more slits.

In an embodiment of the present invention, the ends of the filler include protrusions that protrude beyond the end of the folding portion.

In an embodiment of the present invention, the ends of the filler have a rounded shape.

In an embodiment of the present invention, the first row slits include a plurality of slits arranged in a first direction different from a direction in which the folding portion is extended, and wherein the filler is disposed in all of the plurality of slits of the first row slits.

In an embodiment of the present invention, first ends of the filler that are disposed in the plurality of slits protrude beyond an end of the folding portion and have a rounded surface, and wherein second ends, opposite to the first ends, of the filler that are disposed in the plurality of slits have a flat surface.

In an embodiment of the present invention, the ends of the filler include recesses that are recessed from the end of the folding portion.

In an embodiment of the present invention, the end of the folding portion includes portions where no bar is disposed.

In an embodiment of the present invention, the filler is disposed entirely in the first row slits.

### BRIEF DESCRIPTION OF THE DRAWINGS

The above and other aspects and features of the present invention will become more apparent by describing in detail embodiments thereof with reference to the attached drawings, in which:

FIG. 1 is a perspective view illustrating a display device in an unfolded state according to an embodiment of the present invention.

FIG. 2 is a perspective view illustrating a display device in a folded state according to an embodiment of the present invention.

FIG. 3 is a perspective view illustrating a display device in an unfolded state according to an embodiment of the present invention.

FIG. 4 is a perspective view illustrating a display device in a folded state according to an embodiment of the present invention.

FIG. 5 is a cross-sectional view illustrating a display device according to an embodiment of the present invention.

FIG. 6 is a cross-sectional view illustrating a display panel according to an embodiment of the present invention.

FIG. 7 is a plan view illustrating a panel support member according to an embodiment of the present invention.

FIG. 8 is an enlarged view of area A of FIG. 7.

FIG. 9 is a plan view illustrating a display panel and a panel support member according to an embodiment of the present invention.

FIG. 10 is a plan view showing a panel support member according to an embodiment of the present invention.

FIG. 11 is an enlarged view of area B of FIG. 10.

FIG. 12 is a plan view illustrating a panel support member according to an embodiment of the present invention.

FIG. 13 is an enlarged view of area C of FIG. 12.

FIG. 14 is a plan view illustrating a panel support member according to an embodiment of the present invention.

FIG. 15 is an enlarged view of area D of FIG. 14.

FIG. 16 is a plan view illustrating a panel support member according to an embodiment of the present invention.

FIG. 17 is an enlarged view of area E of FIG. 16.

FIG. 18 is a plan view illustrating a panel support member according to an embodiment of the present invention.

FIG. 19 is an enlarged view of area F of FIG. 18.

### DETAILED DESCRIPTION OF THE EMBODIMENTS

The present invention will now be described more fully hereinafter with reference to the accompanying drawings. The present invention may, however, be embodied in different forms and should not be construed as limiting of the present invention.

It will also be understood that when a layer is referred to as being “on” another layer or substrate, it can be directly on the other layer or substrate, or intervening layers may also be present. The same reference numbers may indicate the same components throughout the specification and drawings, and thus, repetitive descriptions may be omitted.

Hereinafter, embodiments of the present invention will be described in detail with reference to the accompanying drawings.

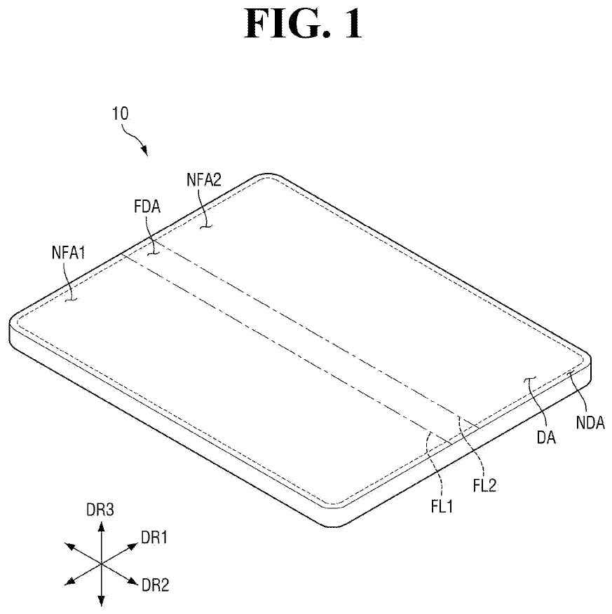

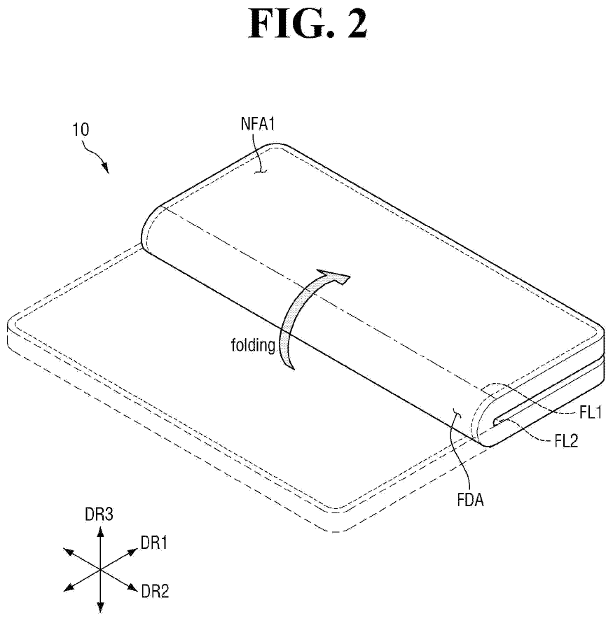

FIG. 1 is a perspective view illustrating a display device in an unfolded state according to an embodiment of the present invention. FIG. 2 is a perspective view illustrating a display device in a folded state according to an embodiment of the present invention.

Referring to FIGS. 1 and 2, FIG. 1 shows a first state of the display device 10 when it is not folded over folding lines FL1 and FL2. In other words, FIG. 1 shows that the first state of the display device 10 is an unfolded state. FIG. 2 shows a second state of the display device 10 when it is folded over the folding lines FL1 and FL2.

A display device 10 according to the embodiment of the present invention is for displaying moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things.

As shown in FIGS. 1 and 2, a first direction DR1 may refer to a direction that is parallel to a first side of the display device 10, for example, the horizontal direction of the display device 10 when viewed from the top. A second direction DR2 may refer to a direction that is parallel to a second side of the display device 10 that meets the first side of the display device 10, for example, the vertical direction of the display device 10 when viewed from the top. A third direction DR3 may refer to the thickness direction of the display device 10.

The display device 10 may have a quadrangular shape, such as a rectangular shape when viewed from the top. Each of the corners of the display device 10 may form a right angle or may be rounded when viewed from the top. For example, the front surface of the display device 10 may include two shorter sides extended in the first direction DR1 and two longer sides extended in the second direction DR2.

The display device 10 may include the display area DA and a non-display area NDA. The shape of the display area DA may follow the shape of the display device 10 when viewed from the top. For example, when the display device 10 has a rectangular shape when viewed from the top, the display area DA may also have a rectangular shape when viewed from the top.

The display area DA may include a plurality of pixels to display images. The non-display area NDA might not include pixels and thus might not display images. The non-display area NDA may be disposed around the display area DA. The non-display area NDA may at least partially surround the display area DA, but the embodiments of the present invention are not limited thereto. The display area DA may be partially surrounded by the non-display area NDA.

The display device 10 may stay either in a first state when it is an unfolded state or a second state when it is a bent state. The display device 10 may be folded inward so that a part of the display device DA faces another part (e.g., in-folding manner), as shown in FIG. 2. In this instance, a part of the front surface of the display device 10 may face another part of the front surface when it is folded. In addition, the display device 10 may be folded outward (e.g., out-folding manner) such that a part of the rear surface faces another part of the second surface when it is folded.

The display device 10 may include a folding area FDA, a first non-folding area NFA1, and a second non-folding area NFA2. The display device 10 can be bent or folded at the folding area FDA, while it cannot be bent or folded at the first non-folding area NFA1 and the second non-folding area NFA2. According to an embodiment of the present invention, the first non-folding area NFA1 and the second non-folding area NFA2 may be flat areas of the display device 10.

The first non-folding area NFA1 may be disposed on one side, for example, the left side of the folding area FDA. The second non-folding area NFA2 may be disposed on the opposite side, for example, the right side of the folding area FDA. The folding area FDA may be defined by the first folding line FL1 and the second folding line FL2, where the display device 10 can be bent with a predetermined curvature. The first folding line FL1 may be the boundary between the folding area FDA and the first non-folding area NFA1, and the second folding line FL2 may be the boundary between the folding area FDA and the second non-folding area NFA2.

The first folding line FL1 and the second folding line FL2 may be extended in the second direction DR2 as shown in FIGS. 1 and 2, and the display device 10 may be folded along the first direction DR1. Accordingly, the length of the display device 10 in the first direction DR1 may be reduced to about half, so that the display device 10 is easy to carry.

When the first folding line FL1 and the second folding line FL2 are extended in the second direction DR2 as shown in FIGS. 1 and 2, the length of the folding area FDA in the second direction DR2 may be larger than the length of the folding area FDA in the first direction DR1. In addition, the length of the first non-folding area NFA1 in the second direction DR2 may be larger than the length of the first non-folding area NFA1 in the first direction DR1. The length of the second non-folding area NFA2 in the second direction DR2 may be larger than the length of the second non-folding area NFA2 in the first direction DR1.

Each of the display area DA and the non-display area NDA may overlap at least one of the folding area FDA, the first non-folding area NFA1, or the second non-folding area NFA2. In the example shown in FIGS. 1 and 2, each of the display area DA and the non-display area NDA overlaps the folding area FDA, the first non-folding area NFA1 and the second non-folding area NFA2.

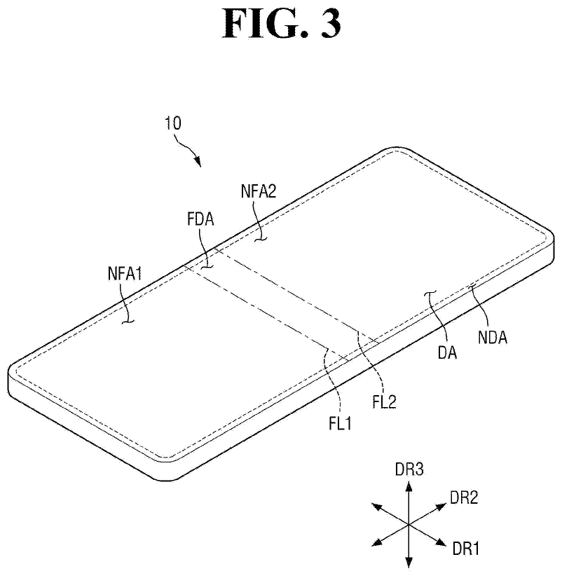

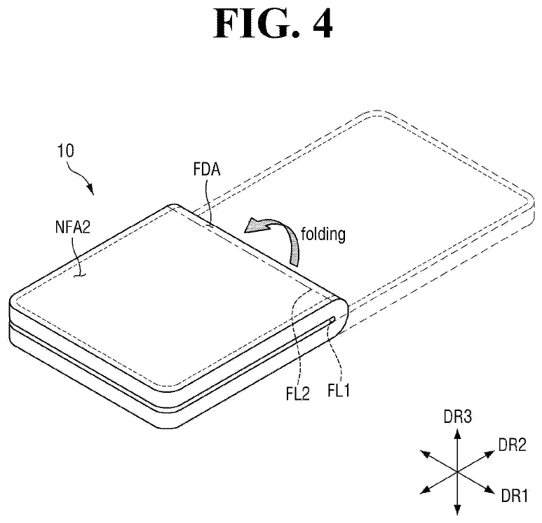

FIG. 3 is a perspective view illustrating a display device in an unfolded state according to an embodiment of the present invention. FIG. 4 is a perspective view illustrating a display device in a folded state according to an embodiment of the present invention.

The embodiment of FIGS. 3 and 4 is substantially identical to the embodiment of FIGS. 1 and 2 except that a first folding line FL1 and a second folding line FL2 are extended in the first direction DR1 and a display device 10 can be folded in the second direction DR2, so that the length of the display device 10 in the second direction DR2 can be reduced by approximately half. Therefore, the elements of FIGS. 3 and 4 that are identical to those of FIGS. 1 and 2 will not be described to avoid redundancy.

Referring to FIGS. 3 and 4, FIG. 3 shows a first state in which the display device 10 is unfolded, and FIG. 4 shows a second state in which the display device 10 is folded over the folding lines FL1 and FL2.

In the first state in which the display device 10 is unfolded, the longer sides of the display device 10 may be extended in the second direction DR2, and the shorter sides of the display device 10 may be extended in the first direction DR1.

The first folding line FL1 and the second folding line FL2 may be extended in the first direction DR1 as shown in FIGS. 3 and 4, and the display device 10 may be folded in the second direction DR2.

The first non-folding area NFA1 may be disposed on one side, for example, the lower side of the folding area FDA. The second non-folding area NFA2 may be disposed on the opposite side, for example, the upper side of the folding area FDA.

When the first folding line FL1 and the second folding line FL2 are extended in the first direction DR1 as shown in FIGS. 3 and 4, the length of the folding area FDA in the first direction DR1 may be larger than the length of the folding area FDA in the second direction DR2. In addition, the length of the first non-folding area NFA1 in the second direction DR2 may be larger than the length of the first non-folding area NFA1 in the first direction DR1. The length of the second non-folding area NFA2 in the second direction DR2 may be larger than the length of the second non-folding area NFA2 in the first direction DR1.

In the following description, the embodiment of FIGS. 1 and 2 will be described as an example for convenience of illustration, but the present invention is not limited thereto. The following description may be equally applied to the embodiment of FIGS. 3 and 4.

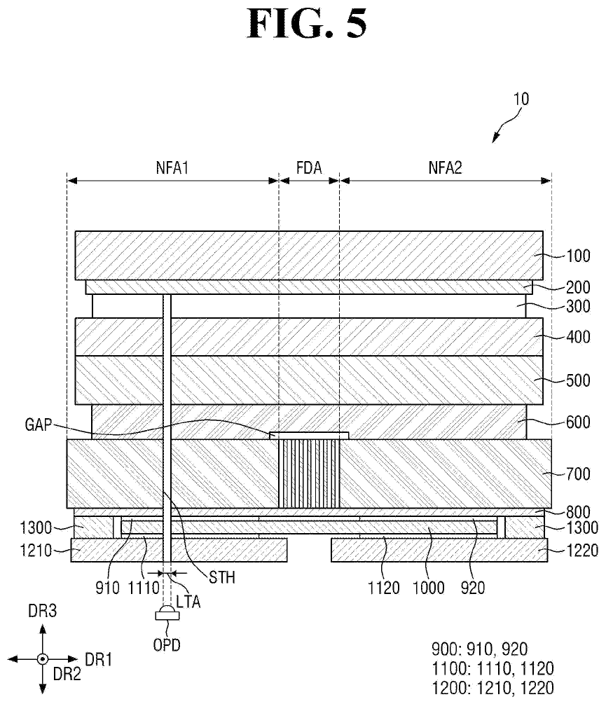

FIG. 5 is a cross-sectional view illustrating a display device according to an embodiment of the present invention.

Referring to FIG. 5, the display device 10 according to an embodiment of the present invention may include a first upper protection member 100 (or a first upper protection layer), a window member 200, a first adhesive member 300 (or a first adhesive), a second upper protection member 400 (or a second upper protection layer), a display panel 500, a lower protection member 600 (or a lower protection layer), a panel support member 700 (or a panel support layer), a buffer member 800 (or a buffer layer), a second adhesive member 900 (or a second adhesive), a lower functional member 1000 (or a lower functional layer), a third adhesive member 1100 (or a third adhesive), a metal support member 1200 (or a metal support layer), and an anti-permeation member 1300 (or an anti-permeation layer).

The display panel 500 may be a panel for displaying images. The display panel 500 may be, for example, an organic light-emitting display panel including an organic light-emitting layer, a quantum-dot light-emitting display panel including a quantum-dot light-emitting layer, an inorganic light-emitting display panel using inorganic semiconductor elements as the light-emitting elements, and a micro light-emitting display panel using micro light-emitting diodes as the light-emitting elements. In the following description, an organic light-emitting display panel is employed as the display panel 500. It is, however, to be understood that the present invention is not limited thereto.

The display panel 500 may include a light transmission area LTA overlapping an optical device OPD in the third direction DR3. The optical device OPD is an optical sensor that detects light, and may be, for example, a camera sensor, a proximity sensor, and an illuminance sensor. The light transmission area LTA may be a part of the display area DA.

The light transmission area LTA may include a transmissive area that allows light to pass. In addition, the light transmission area LTA may be a through hole that penetrates the display panel 500. The transmittance of the light transmission area LTA may be higher than the transmittance of the portion of the display area DA that does not include the light transmission area LTA. In addition, due to the transmissive area of the light transmission area LTA, the density or integration degree of pixels in the light transmission area LTA may be lower than the density or integration degree of pixels in the display area DA that does not include the light transmission area LTA. For example, the number of pixels per unit area in the light transmission area LTA may be smaller than the number of pixels per unit area in the display area DA excluding the light transmission area LTA. In addition, pixels per inch (PPI) in the light transmission area LTA may be smaller than PPI in the display area DA that does not include the light transmission area LTA.

The second upper protection member 400 may be disposed on the front surface of the display panel 500. The second upper protection member 400 can mitigate shock to protect the display panel 500 from external impact. For example, the second upper protection member 400 may include a material having high flexibility and high rigidity.

The window member 200 may be attached to the front surface of the second upper protection member 400 by the first adhesive member 300. The window member 200 is made of a transparent material, and may be, for example, glass or plastic. For example, the window member 200 may be an ultra thin glass (UTG) that has a thickness of about 0.1 mm or less or a transparent polyimide film.

The first adhesive member 300 may be a transparent adhesive film or a transparent adhesive resin. For example, the first adhesive member 300 may include a transparent adhesive such as a pressure sensitive adhesive (PSA) and an optically clear adhesive (OCA). The first adhesive member 300 may include an acrylic adhesive material.

The first upper protection member 100 may be disposed on the front surface of the window member 200. The first upper protection member 100 may perform at least one of the following functions: shock absorption, anti-scratch, anti-fingerprint, anti-glare, or anti-scattering when the window member 200 is broken. For example, the first upper protective member 100 may include a material having high flexibility and resistance to scratches.

The lower protection member 600 may be disposed on the rear surface of the display panel 500. The lower protection member 600 may support the display panel 500 and protect the rear surface of the display panel 500. The lower protection member 600 may be made of plastic such as polyethylene terephthalate (PET) and polyimide.

According to an embodiment of the present invention, to facilitate folding of the display device 10, at least a part of the lower protection member 600 may be removed from the folding area FDA of the display device 10. For example, as shown in FIG. 5, the lower protection member 600 may include a gap GAP in the folding area FDA. In an embodiment of the present invention, portions of the gap GAP may be in the folding area FDA and first and second non-folding areas NFA1 and NFA2.

The gap GAP may be located adjacent to the upper surface of the panel support member 700. In the display device 10 according to an embodiment of the present invention, since the lower protection member 600 includes the gap GAP, it is possible to prevent the panel support member 700 that has high rigidity and the lower protection member 600 from being in direct contact with each other in the folding area FDA. By doing so, it is possible to reduce folding stress of the display device 10.

The panel support member 700 may be disposed on the rear surface of the lower protection member 600. The panel support member 700 may be a rigid member that does not easily change shape or volume due to external pressure. The panel support member 700 may support the display panel 500.

According to an embodiment of the present invention, the panel support member 700 may be a metal plate. For example, the panel support member 700 may be a metal plate and may be made of metal or metal alloy. For example, the panel support member 700 may include, but is not limited to, copper (Cu), aluminum (Al), stainless steel (SUS), and/or an alloy thereof.

According to an embodiment of the present invention, the panel support member 700 may be a polymer including carbon fiber or glass fiber. In this instance, since the panel support member 700 is formed of a polymer including carbon fiber or glass fiber, electromagnetic signals of a digitizer member in the display device 10 can pass through. Therefore, the panel support member 700 that can support the display panel 500 without lowering the touch sensitivity of the digitizer member may be provided.

The panel support member 700 may include a through hole STH overlapping the optical device OPD in the third direction DR3. The through hole STH may overlap the light transmission area LTA of the display panel 500 in the third direction DR3. The area of the through hole STH may be greater than or equal to the area of the light transmission area LTA. The optical device OPD may detect light incident from the front of the display device 10 through the light transmission area LTA and the through hole STH.

The panel support member 700 may include a lattice pattern that is disposed on the folding area FDA so that it can easily bend in the folding area FDA. As the panel support member 700 includes the lattice pattern that is disposed in the folding area FDA, the panel support member 700 can be easily bent when the display device 10 is folded.

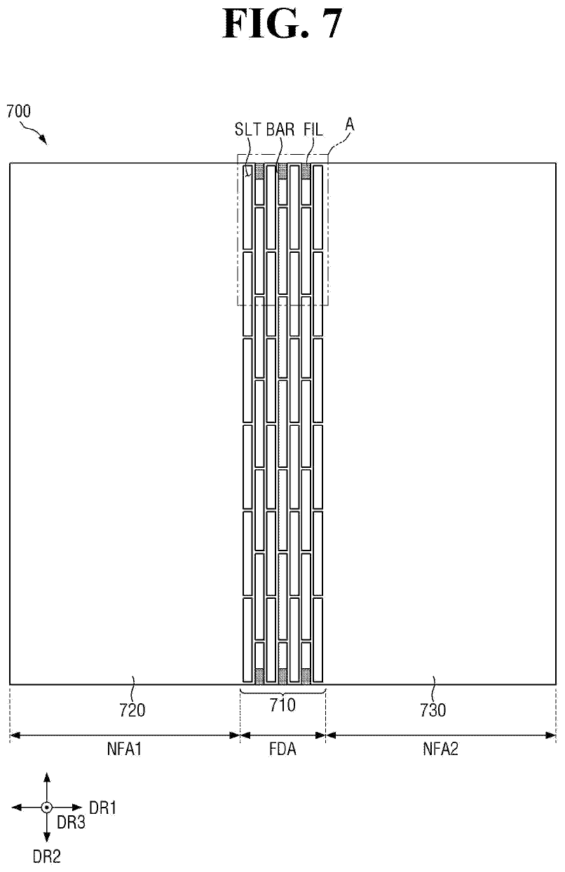

The panel support member 700 will be described in detail with reference to FIG. 7 and the like.

The buffer member 800 can reduce folding stress of the panel support member 700 that has a high rigidity when the display device 10 is folded. The buffer member 800 may include a highly elastic material to absorb shock. For example, the buffer member 800 may include, but is not limited to, thermoplastic polyurethane (TPU).

In embodiments of the present invention, the display device 10 may further include a digitizer member. The digitizer member may be disposed on the rear surface of the buffer member 800. The digitizer member may include electrode patterns for sensing proximity or contact of an electronic pen such as a stylus pen supporting an electromagnetic resonance (EMR) technology. The digitizer member may detect a magnetic field or an electromagnetic signal emitted from the electronic pen based on the electrode patterns, and may determine touch coordinates of the point where the detected magnetic field or electromagnetic signal is largest.

Magnetic metal powder may be disposed on the rear surface of the digitizer member. In this instance, a magnetic field or electromagnetic signal passing through the digitizer member may flow into the magnetic metal powder. Therefore, by virtue of the magnetic metal powder, it is possible to reduce the amount of the magnetic field or the electromagnetic signal from the digitizer member to the rear surface of the display device 10.

The lower functional member 1000 may be attached to the rear surface of the buffer member 800 by the second adhesive member 900. The lower functional member 1000 may include at least one of a light-blocking layer for absorbing light incident from outside, a buffer layer for absorbing external shock, or a heat sink layer for efficiently discharging heat from the display panel 500.

The light-blocking layer can block transmission of light, thereby preventing elements disposed under the light-blocking layer from being seen from above the display panel 500. The light-blocking layer may include a light-absorbing material such as a black pigment and a black dye.

The buffer layer can absorb external shock to prevent the display panel 500 from being damaged. The buffer layer may be made up of a single layer or multiple layers. For example, the buffer layer may be formed of a polymer resin such as polyurethane, polycarbonate, polypropylene and polyethylene, or may be formed of a material having elasticity such as a rubber and a sponge obtained by foaming a urethane-based material or an acrylic-based material.

The heat sink layer may include a first heat dissipation layer that includes graphite or carbon nanotubes, and a second heat dissipation layer that is formed of a thin metal film such as copper, nickel, ferrite and silver, which can block electromagnetic waves and have high thermal conductivity.

The second adhesive member 900 may be a transparent adhesive film or a transparent adhesive resin. For example, the second adhesive member 900 may include a transparent adhesive such as a pressure sensitive adhesive (PSA) and an optically clear adhesive (OCA). The second adhesive member 900 may include an acrylic adhesive material.

The second adhesive member 900 might not be disposed in the folding area FDA of the display device 10 to facilitate the folding of the display device 10. For example, the second adhesive member 900 may include a (2-1) adhesive member 910 that is disposed in the first non-folding area NFA1, and a (2-2) adhesive member 920 that is disposed in the second non-folding area NFA2. The (2-1) adhesive member 910 and the (2-2) adhesive member 920 may be spaced apart from each other with the folding area FDA therebetween.

The metal support member 1200 may be attached to the rear surface of the lower functional member 1000 by the third adhesive member 1100. The metal support member 1200 may include a material having high rigidity to support the lower functional member 1000. For example, the metal support member 1200 may include, but is not limited to, stainless steel such as SUS316.

The metal support member 1200 might not be disposed in the folding area FDA of the display device 10 to facilitate the folding of the display device 10. For example, the metal support member 1200 may include a first metal support member 1210 that is disposed in the first non-folding area NFA1, and a second metal support member 1220 that is disposed in the second non-folding area NFA2. The first metal support member 1210 and the second metal support member 1220 may be spaced apart from each other with the folding area FDA therebetween. In an embodiment of the present invention, a portion of the first metal support member 1210 and a portion of the second metal support member 1220 may be disposed in the folding area FDA.

The third adhesive member 1100 may be a transparent adhesive film or a transparent adhesive resin. For example, the third adhesive member 1100 may include a transparent adhesive such as a pressure sensitive adhesive (PSA) and an optically clear adhesive (OCA). The third adhesive member 1100 may include an acrylic adhesive material.

The third adhesive member 1100 might not be disposed in the folding area FDA of the display device 10 to facilitate the folding of the display device 10. For example, the third adhesive member 1100 may include a (3-1) adhesive member 1110 that is disposed in the first non-folding area NFA1, and a (3-2) adhesive member 1120 that is disposed in the second non-folding area NFA2. The (3-1) adhesive member 1110 and the (3-2) adhesive member 1120 may be spaced apart from each other with the folding area FDA therebetween.

The anti-permeation member 1300 may be disposed on the rear surface of the buffer member 800. The anti-permeation member 1300 may be disposed between the buffer member 800 and the metal support member 1200 in the third direction DR3. The anti-permeation member 1300 may cover side surfaces of the second adhesive member 900, the lower functional member 1000, and third adhesive member 1100.

The anti-permeation member 1300 may be disposed at the edge of the buffer member 800. The anti-permeation member 1300 may be disposed on one side of the lower functional member 1000. Although the anti-permeation member 1300 is disposed at the edge of the buffer member 800 or on one side of the lower functional member 1000 only in the first direction DR1 in the drawings, but the present invention is not limited thereto. For example, the anti-permeation member 1300 may be disposed to surround the lower functional member 1000 on the plane in the first and second directions DR1 and DR2.

The anti-permeation member 1300 may be a waterproof (dust-proof) tape or a waterproof (dust-proof) member that attaches the rear surface of the buffer member 800 to the front surface of the metal support member 1200. Accordingly, the anti-permeation member 1300 may prevent permeation of moisture or dust into the display device 10. That is to say, a display device 10 with waterproof and dustproof capabilities can be produced.

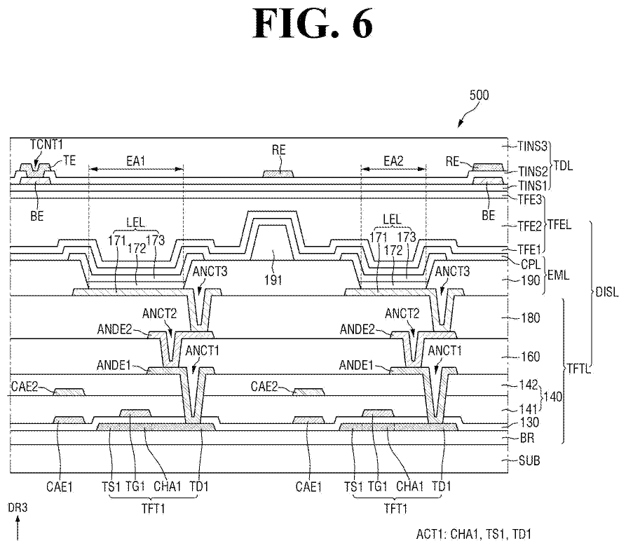

FIG. 6 is a cross-sectional view illustrating a display panel according to an embodiment of the present invention.

Referring to FIG. 6, the display panel 500 may include a substrate SUB, a display layer DISL that is disposed on the substrate SUB, and a touch detecting layer TDL that is disposed on the display layer DISL. The display layer DISL may include a thin-film transistor layer TFTL, an emission material layer EML, and an encapsulation layer TFEL.

The thin-film transistor layer TFTL may be disposed on the substrate SUB. The thin-film transistor layer TFTL may include a barrier layer BR, a thin-film transistor TFT1, a first capacitor electrode CAE1, a second capacitor electrode CAE2, a first anode connection electrode ANDE1, a second anode connection electrode ANDE2, a gate insulator 130, a first interlayer dielectric film 141, a second interlayer dielectric film 142, a first planarization film 160, a second planarization film 180.

The substrate SUB may be made of an insulating material such as a polymer resin. For example, the substrate SUB may be made of polyimide. The substrate SUB may be a flexible substrate that can be bent, folded, or rolled.

The barrier film BR may be disposed on the substrate SUB. The barrier film BR is a film for protecting the thin-film transistors of the thin-film transistor layer TFTL and an emissive layer 172 of the emission material layer EML. The barrier film BR may be made up of multiple inorganic films stacked on one another alternately. For example, the barrier film BR may be made up of multiple layers in which one or more inorganic layers of a silicon nitride layer, a silicon oxynitride layer, a silicon oxide layer, a titanium oxide layer and an aluminum oxide layer are alternately stacked on one another.

The thin-film transistors TFT1 may be disposed on the barrier film BR. An active layer ACT1 of the thin-film transistor TFT1 may be disposed on the barrier layer BR. The active layer ACT1 of the thin-film transistor TFT1 may include, for example, polycrystalline silicon, monocrystalline silicon, low-temperature polycrystalline silicon, amorphous silicon, or an oxide semiconductor.

The active layer ACT1 may include a channel region CHAI, a source region TS1 and a drain region TD1. The channel region CHAI may overlap with a gate electrode TG1 in the third direction DR3. The source region TS1 may be disposed on one side of the channel region CHAI, and the drain region TD1 may be disposed on the opposite side of the channel region CHAI. The source region TS1 and the drain region TD1 might not overlap with the gate electrode TG1 in the third direction DR3. The source region TS1 and the drain region TD1 may be formed by being doped with a silicon semiconductor or an oxide semiconductor with ions or impurities to have conductivity.

The gate insulator 130 may be disposed on the active layer ACT1 of the thin-film transistor TFT1. The gate insulator 130 may be formed of an inorganic layer, for example, a silicon nitride layer, a silicon oxynitride layer, a silicon oxide layer, a titanium oxide layer, or an aluminum oxide layer.

The gate electrode TG1 of the thin-film transistor TFT1 and the first capacitor electrode CAE1 may be disposed on the gate insulator 130. The gate electrode TG1 may overlap with the channel region CHAI in the third direction DR3. Although the gate electrode TG1 and the first capacitor electrode CAE1 are spaced apart from each other in the example shown in FIG. 6, the gate electrode TG1 and the first capacitor electrode CAE1 may be connected with each other as a single piece. The gate electrode TG1 and the first capacitor electrode CAE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric film 141 may be disposed on the gate electrode TG1 of the thin-film transistor TFT1 and the first capacitor electrode CAE1. The first interlayer dielectric film 141 may be formed of an inorganic layer, for example, a silicon nitride layer, a silicon oxynitride layer, a silicon oxide layer, a titanium oxide layer, or an aluminum oxide layer. The first interlayer dielectric film 141 may be made of a plurality of inorganic films.

The second capacitor electrode CAE2 may be disposed on the first interlayer dielectric layer 141. The second capacitor electrode CAE2 may overlap the first capacitor electrode CAE1 of the thin-film transistor TFT1 in the third direction DR3. In addition, when the gate electrode TG1 and the first capacitor electrode CAE1 are formed as a single piece, the second capacitor electrode CAE2 may overlap the gate electrode TG1 in the third direction DR3. Since the first interlayer dielectric layer 141 has a predetermined dielectric constant, a capacitor can be formed by the first capacitor electrode CAE1, the second capacitor electrode CAE2 and the first interlayer dielectric layer 141 that is disposed therebetween. The second capacitor electrode CAE2 may be made up of a single layer or multiple layers of one of, for example, molybdenum (Mo), aluminum (Al), chromium (Cr), gold (Au), titanium (Ti), nickel (Ni), neodymium (Nd) and copper (Cu) or an alloy thereof.

A second interlayer dielectric layer 142 may be disposed over the second capacitor electrode CAE2. The second interlayer dielectric film 142 may be formed of an inorganic layer, for example, a silicon nitride layer, a silicon oxynitride layer, a silicon oxide layer, a titanium oxide layer, or an aluminum oxide layer. The second interlayer dielectric film 142 may be made of a plurality of inorganic films.

A first anode connection electrode ANDE1 may be disposed on the second interlayer dielectric layer 142. The first anode connection electrode ANDE1 may be connected to the drain electrode DT1 of the thin-film transistor TFT1 through a first connection contact hole ANCT1 that penetrates the gate insulator 130, the first interlayer dielectric film 141 and the second interlayer dielectric film 142. The first anode connection electrode ANDE1 may be made up of a single layer or multiple layers of one of, for example, molybdenum (Mo), aluminum (Al), chromium (Cr), gold (Au), titanium (Ti), nickel (Ni), neodymium (Nd) and copper (Cu) or an alloy thereof.

A first planarization film 160 may be disposed over the first anode connection electrode ANDE1 and may provide a flat surface over level differences due to the thin-film transistor TFT1. The first planarization film 160 may be formed of an organic layer such as an acryl resin, an epoxy resin, a phenolic resin, a polyamide resin and a polyimide resin.

A second anode connection electrode ANDE2 may be disposed on the first planarization layer 160. The second anode connection electrode ANDE2 may be connected to the first anode connection electrode ANDE1 through a second connection contact hole ANCT2 that penetrates the first planarization layer 160. The second anode connection electrode ANDE2 may be made up of a single layer or multiple layers of one of, for example, molybdenum (Mo), aluminum (Al), chromium (Cr), gold (Au), titanium (Ti), nickel (Ni), neodymium (Nd) and copper (Cu) or an alloy thereof.

A second planarization film 180 may be disposed on the second anode connection electrode ANDE2. The second planarization film 180 may be formed as an organic layer such as an acryl resin, an epoxy resin, a phenolic resin, a polyamide resin and a polyimide resin.

An emission material layer EML that includes light-emitting elements LEL and a bank 190 may be disposed on the second planarization film 180. Each of the light-emitting elements LEL includes a pixel electrode 171, an emissive layer 172, and a common electrode 173.

The pixel electrode 171 may be disposed on the second planarization film 180. The pixel electrode 171 may be connected to the second anode connection electrode ANDE2 through a third connection contact hole ANCT3 that penetrates the second planarization film 180.

In the top-emission structure in which light exits from the emissive layer 172 toward the common electrode 173, the pixel electrode 171 may be made of a metal material having a high reflectivity such as a stack structure of aluminum and titanium (Ti/Al/Ti), a stack structure of aluminum (Al) and ITO (Indium Tin Oxide) (ITO/Al/ITO), an APC alloy and a stack structure of an APC alloy and ITO (ITO/APC/ITO). The APC alloy is an alloy of silver (Ag), palladium (Pd) and copper (Cu).

The bank 190 may partition the pixel electrode 171 on the second planarization film 180 to define the emission areas EA1 and EA2 of the light-emitting elements LEL. The bank 190 may be disposed to cover the edges of the pixel electrode 171. The bank 190 may be formed of an organic layer such as an acryl resin, an epoxy resin, a phenolic resin, a polyamide resin and a polyimide resin.

In each of the first emission area EA1 and the second emission area EA2, the pixel electrode 171, the emissive layer 172 and the common electrode 173 are stacked on one another sequentially, so that holes from the pixel electrode 171 and electrons from the common electrode 173 are recombined with each other in the emissive layer 172 to emit light.

The emissive layer 172 may be disposed on the pixel electrode 171 and the bank 190. The emissive layer 172 may include an organic material to emit light of a certain color. For example, the emissive layer 172 may include a hole transporting layer, an organic material layer, and an electron transporting layer.

The common electrode 173 may be disposed on the emissive layer 172. The common electrode 173 may be disposed to cover the emissive layer 172. The common electrode 173 may be a common layer formed commonly across the first emission area EA1 and the second emission area EA2.

In the top-emission organic light-emitting diode, the common electrode 173 may be formed of, for example, a transparent conductive material (TCP) such as ITO and IZO that can transmit light, or a semi-transmissive conductive material such as magnesium (Mg), silver (Ag) and an alloy of magnesium (Mg) and silver (Ag). When the common electrode 173 is formed of a semi-transmissive metal material, the light extraction efficiency can be increased by using microcavities.

A spacer 191 may be disposed on the bank 190. The spacer 191 may support a mask during a process of fabricating the emission layer 172. The spacer 191 may be formed of an organic layer such as an acryl resin, an epoxy resin, a phenolic resin, a polyamide resin and a polyimide resin.

According to embodiments of the present invention, the display panel 500 may further include a capping layer CPL that is disposed on the common electrode 173. The capping layer CPL may be made of an inorganic material. For example, the capping layer CPL may include at least one of silicon nitride, aluminum nitride, zirconium nitride, titanium nitride, hafnium nitride, tantalum nitride, silicon oxide, aluminum oxide, titanium oxide, tin oxide, cerium oxide or silicon oxynitride.

An encapsulation layer TFEL may be disposed on the common electrode 173. The encapsulation layer TFEL may include at least one inorganic layer to prevent permeation of oxygen or moisture into the emission material layer EML. In addition, the encapsulation layer TFEL may include at least one organic film to protect the emission material layer EML from particles such as dust. For example, the encapsulation layer TFEL may include a first inorganic encapsulation layer TFE1, an organic encapsulation layer TFE2 and a second inorganic encapsulation layer TFE3.

The first inorganic encapsulation film TFE1 may be disposed on the common electrode 173. The organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, etc.

A touch detecting layer TDL may be disposed on the encapsulation layer TFEL. The touch detecting layer TDL includes a first touch insulating film TINS1, connection electrodes BE, a second touch insulating film TINS2, the driving electrodes TE, the sensing electrodes RE, and a third touch insulating film TINS3.

The first touch insulating film TINS1 may be disposed on the encapsulation layer TFEL. The first touch insulating film TINS1 may be formed of an inorganic layer, for example, a silicon nitride layer, a silicon oxynitride layer, a silicon oxide layer, a titanium oxide layer, or an aluminum oxide layer.

The connection electrode BE may be disposed on the first touch insulating film TINS1. The connection electrode BE may be made up of a single layer or multiple layers of at least one of molybdenum (Mo), aluminum (Al), chromium (Cr), gold (Au), titanium (Ti), nickel (Ni), neodymium (Nd) and copper (Cu) or an alloy thereof.

The second touch insulating film TINS2 may be disposed over the connection electrodes BE and disposed on the first touch insulating film TINS1. The second touch insulating layer TINS2 may be formed of an inorganic layer, for example, a silicon nitride layer, a silicon oxynitride layer, a silicon oxide layer, a titanium oxide layer, or an aluminum oxide layer. In addition, the second touch insulating layer TINS2 may be formed of an organic layer such as an acryl resin, an epoxy resin, a phenolic resin, a polyamide resin and a polyimide resin.

The driving electrodes TE and the sensing electrodes RE may be disposed on the second touch insulating film TINS2. The driving electrodes TE and the sensing electrodes RE may be made up of a single layer or multiple layers of at least one of molybdenum (Mo), aluminum (Al), chromium (Cr), gold (Au), titanium (Ti), nickel (Ni), neodymium (Nd) and copper (Cu) or an alloy thereof.

Each of the driving electrodes TE and the sensing electrodes RE may overlap with the connection electrodes BE in the third direction DR3. The driving electrodes TE may be connected to the connection electrodes BE through touch contact holes TCNT1 penetrating through the first touch insulating film TINS1.

The third touch insulating film TINS3 may be formed on the driving electrodes TE and the sensing electrodes RE. The third touch insulating layer TINS3 may provide a flat surface over the driving electrodes TE, the sensing electrodes RE and the connection electrodes BE, all of which have different heights from one another. The third touch insulating film TINS3 may be formed of an organic layer such as an acryl resin, an epoxy resin, a phenolic resin, a polyamide resin and a polyimide resin.

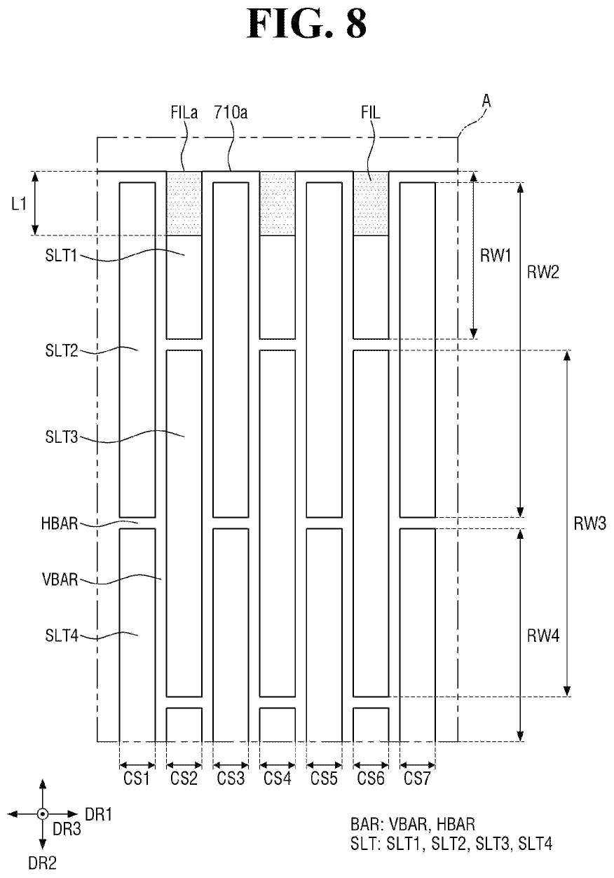

FIG. 7 is a plan view illustrating a panel support member according to an embodiment of the present invention. FIG. 8 is an enlarged view of area A of FIG. 7.

Referring to FIGS. 7 and 8, the panel support member 700 may include a folding portion 710, a first non-folding portion 720 and a second non-folding portion 730. The folding portion 710 may be disposed in the folding area FDA. The first non-folding portion 720 may be disposed in the first non-folding area NFA1, and the second non-folding portion 730 may be disposed in the second non-folding area NFA2.

The folding portion 710 may be folded when the display device 10 is folded. The folding portion 710 may be disposed between the first non-folding portion 720 and the second non-folding portion 730 in the first direction DR1.

The first non-folding portion 720 and the second non-folding portion 730 might not be folded when the display device 10 is folded. The first non-folding portion 720 may be disposed on one side of the folding portion 710 in the first direction DR1, and the second non-folding portion 730 may be disposed on the opposite side of the folding portion 710 in the first direction DR1.

The folding portion 710 may include a lattice pattern. For example, the folding portion 710 may include a plurality of bars BAR and a plurality of slits SLT that are disposed between the plurality of bars BAR.

The plurality of bars BAR may include a plurality of horizontal bars HBAR that are extended in the first direction DR1, and a plurality of vertical bars VBAR that are extended in the second direction DR2.

Each of the plurality of slits SLT may be a hole penetrating the panel support member 700 in the third direction DR3. The plurality of slits SLT may each extended in the second direction DR2. For example, the length of each of the plurality of slits SLT in the second direction DR2 may be larger than the length of the slit SLT in the first direction DR1. Since the folding portion 710 includes the plurality of slits SLT, the panel support member 700 can have flexibility. That is to say, the folding portion 710 may be stretched in the first direction DR1 when the display device 10 is folded.

In the example shown in FIG. 8, a plurality of slits SLT are disposed in first to seventh slit columns CS1 to CS7 and first to fourth slit rows RW1 to RW4. In addition, a plurality of vertical bars VBAR disposed between the first to seventh slit columns CS1 to CS7, and a plurality of horizontal bars HBAR disposed between the first to fourth slit rows RW1 to RW4. The numbers of the slit rows, the slits, and the bars are not limited thereto.

The first to seventh slit columns CS1 to CS7 may be sequentially arranged in the first direction DR1. The first to seventh slit columns CS1 to CS7 refer to columns in which the slits SLT are arranged in the first direction DR1.

The first to fourth slit rows RW1 to RW4 may be arranged in the second direction DR2. The first to fourth slit rows RW1 to RW4 refer to rows in which the first to fourth row slits SLT1 to SLT4 are disposed, respectively. For example, the second slit row RW2 may at least partially overlap with the first slit row RW1 in the first direction DR1, and at least another portion of the second slit row RW2 may overlap with the third slit row RW3 in the first direction DR1. The first slit row RW1 and the third slit row RW3 might not overlap each other in the first direction DR1. In addition, the third slit row RW3 may at least partially overlap with the second slit row RW2 in the first direction DR1, and at least another portion of the third slit row RW3 may overlap with the fourth slit row RW4 in the first direction DR1. The second slit row RW2 and the fourth slit row RW4 might not overlap each other in the first direction DR1. For example, the plurality of slits SLT may have a staggered arrangement in the first direction DR1 in which some of the plurality of slits SLT are misaligned with each other.

The plurality of vertical bars VBAR may be respectively disposed between adjacent ones of the first to seventh slit columns CS1 to CS7. A plurality of horizontal bars HBAR may be disposed between adjacent one of the first to fourth slit rows RW1 to RW4. For example, some of the horizontal bars HBAR may be disposed between the first slit row RW1 and the third slit row RW3 in the second slit column CS2, the fourth slit column CS4 and the sixth slit column CS6. In addition, some others of the horizontal bars HBAR may be disposed between the second slit row RW2 and the fourth slit row RW4 in the first slit column CS1, the third slit column CS3, the fifth slit column CS5 and the seventh slit column CS7.

The first row slits SLT1 may be disposed in the first slit row RW1. For example, the first row slits SLT1 may be located closer to an end 710a of the folding portion 710 in the second direction DR2 with respect to the plurality of horizontal bars HBAR that are disposed between the first and third slit rows RW1 and RW3. The first row slits SLT1 may be disposed in the second slit column CS2, the fourth slit column CS4 and the sixth slit column CS6.

The second row slits SLT2 may be disposed in the second slit row RW2. For example, the second row slits SLT2 may be located closer to the end 710a of the folding portion 710 in the second direction DR2 with respect to the plurality of horizontal bars HBAR that are disposed between the second and fourth slit rows RW2 and RW4. The second row slits SLT2 may be disposed in the first slit column CS1, the third slit column CS3, the fifth slit column CS5 and the seventh slit column CS7.

The third row slits SLT3 may be disposed in the third slit row RW3. For example, the third row slits SLT3 may be located farther from the end 710a of the folding portion 710 in the second direction DR2 with respect to the plurality of horizontal bars HBAR that is disposed between the first and third slit rows RW1 and RW3. The third row slits SLT3 may be disposed in the second slit column CS2, the fourth slit column CS4 and the sixth slit column CS6.

The fourth row slits SLT4 may be disposed in the fourth slit row RW4. For example, the fourth row slits SLT4 may be located farther from the end 710a of the folding portion 710 in the second direction DR2 with respect to the plurality of horizontal bars HBAR that are disposed between the second and fourth slit rows RW2 and RW4. The fourth row slits SLT4 may be disposed in the first slit column CS1, the third slit column CS3, the fifth slit column CS5 and the seventh slit column CS7.

In the display device 10 according to this embodiment, the first row slits SLT1 may overlap with the end 710a of the folding portion 710 in the first direction DR1. For example, the end 710a of the folding portion 710 may include portions where no bar is disposed. As shown in FIG. 8, in the second slit column CS2, the fourth slit column CS4 and the sixth slit column CS6, no bar is disposed at the end 710a of the folding portion 710 but a plurality of slits SLT may be provided. Accordingly, it is possible to reduce folding stress during folding of the display device 10.

In the display device 10 according to this embodiment, a filler FIL may be disposed at least partially in the first row slits SLT1. The filler FIL may be used to prevent particles from permeating into the first row slits SLT1. The filler FIL can absorb external shock. For example, the filler FIL may include, but is not limited to, a urethane resin, an epoxy resin, an acrylic resin, a silicone resin, or inorganic sealant.

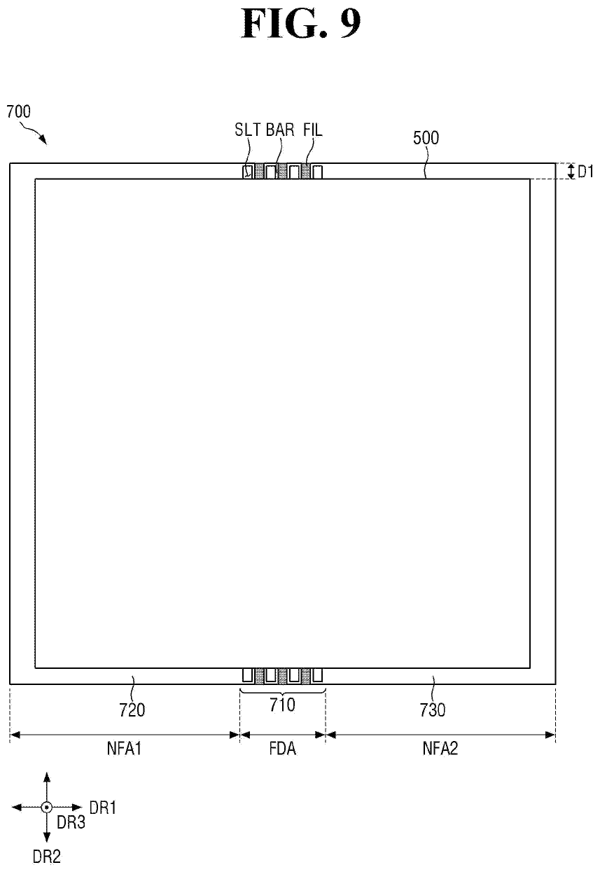

According to an embodiment of the present invention, the filler FIL may be disposed only partially in the first row slits SLT1. For example, the filler FIL may be disposed adjacent to the end 710a of the folding portion 710 in the first row slits SLT1. The filler FIL may have a first length L1 from the end 710a of the folding portion 710. The first length L1 may be equal to a first distance D1 (see FIG. 9) described below with reference to FIG. 9. The first length L1 and the first distance D1 (see FIG. 9) will be described later with reference to FIG. 9.

According to an embodiment of the present invention, ends FILa of the filler FIL may be a substantially flat surface. The ends FILa of the filler FIL may coincide with the end 710a of the folding portion 710. For example, the ends FILa of the filler FIL may be located on the same plane or substantially the same plane as the end 710a of the folding portion 710 that is on the plane that is in the first and third directions DR1 and DR3.

In some embodiments of the present invention, the modulus of the filler FIL may be relatively low. For example, the modulus of the filler FIL may be approximately 15 MPa or less. For example, the modulus of the filler FIL may be approximately 8 MPa to approximately 12 MPa. Since the modulus of the filler FIL is approximately 15 MPa or less according to this embodiment, it is possible to reduce stress that is applied to the plurality of slits SLT and the plurality of bars BAR when the display device 10 is folded and being folded.

As used herein, the modulus means Young's modulus, and is measured according to, for example, ASTM D638 or ASTM D3039.

As the display device 10 according to this embodiment includes the filler FIL that is disposed in the first row slits SLT1, it is possible to prevent particles from permeating into the first row slits SLT1. Accordingly, the reliability of the display device 10 can be increased.

In embodiments of the present invention, the filler FIL might not be disposed in the other row slits other than the first row slits SLT1. For example, the filler FIL might not be disposed in the second to fourth row slits SLT2 to SLT4. In the display device 10 according to this embodiment, the filler FIL is not disposed in the row slits other than the first row slits SLT1, thereby reducing folding stress when the display device 10 is folded.

The filler FIL might not be disposed in the first and second non-folding areas NFA1 and NFA2. For example, the filler FIL might not be disposed at the ends of the first non-folding portion 720 and/or the second non-folding portion 730. By doing so, the width of the panel support member increases in the second direction DR2 due to the width of the filler FIL, thereby preventing a dead space.

Although area A of FIG. 7 has been described above, it is to be understood that the filler FIL may be equally disposed at the lower end of the folding portion 710 of FIG. 7. For example, the filler FIL may be applied at the lower end of the folding portion 710 in substantially the same manner as that of the upper end of the folding portion 710.

FIG. 9 is a plan view illustrating a display panel and a panel support member according to an embodiment of the present invention.

Referring to FIG. 9 in conjunction with FIGS. 7 and 8, the display panel 500 may be smaller than the panel support member 700. For example, the ends of the panel support member 700 may protrude beyond the ends of the display panel 500 in the first and second directions DR1 and DR2.

For example, the end 710a of the folding portion 710 of the panel support member 700 may protrude beyond the end of the display panel 500. For example, the end 710a of the folding portion 710 of the panel support member 700 may protrude beyond the end of the display panel 500 by a first distance D1. Portions of the first row slits SLT1 may be covered by the display panel 500, and the filler FIL, which is disposed in portions of the first row slits SLT1, might not be covered by the display panel 500. Accordingly, at least some of the first row slits SLT1 of the panel support member 700 might not be covered by the display panel 500 and may be exposed to the outside.

As described above with reference to FIG. 8, in the display device 10 according to this embodiment, the filler FIL may be disposed adjacent to the end 710a of the folding portion 710 in the first row slits SLT1. The filler FIL may have the first length L1 from the end 710a of the folding portion 710. The first length L1 may be equal or substantially equal to the first distance D1.

The filler FIL may be disposed in the slits SLT that do not overlap with the display panel 500 in the third direction DR3. For example, the filler FIL may be disposed only in the slits SLT that do not overlap with the display panel 500 in the third direction DR3. The filler FIL may partially be disposed in the slits SLT such that they do not overlap with the display panel 500.

In the display device 10 according to this embodiment, it is possible to reduce folding stress when the display device 10 is folded by partially disposing the filler FIL in the slits SLT such that they do not overlap with the display panel 500.

Hereinafter, display devices according to embodiments of the present invention will be described. In the following description, the same or similar elements will be denoted by the same or similar reference numerals, and redundant descriptions will be omitted or briefly described.

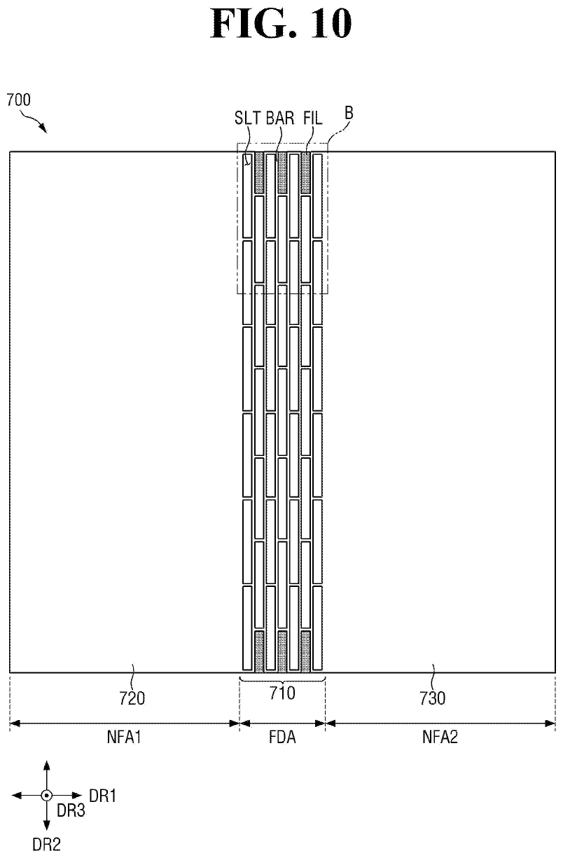

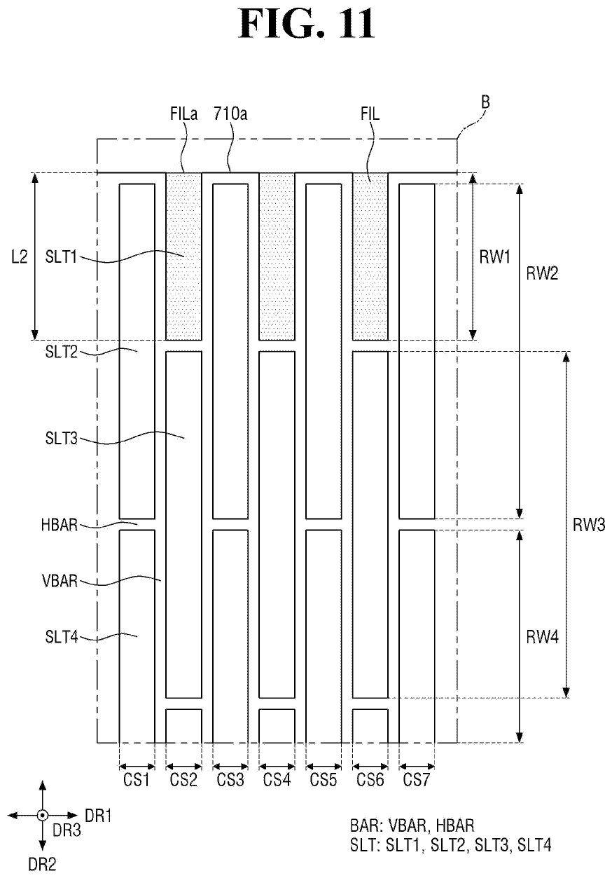

FIG. 10 is a plan view illustrating a panel support member according to an embodiment of the present invention. FIG. 11 is an enlarged view of area B of FIG. 10.

A display device 10 according to the embodiment of FIGS. 10 and 11 is different from the display device 10 according to the embodiment of FIG. 7 and the like in that a filler FIL is disposed entirely in each of first row slits SLT1.

For example, in the display device 10 according to this embodiment, the filler FIL may be disposed entirely in the first row slits SLT1. For example, the filler FIL may be extended in the second direction DR2 in each of the first row slits SLT1. The filler FIL may be used to fill each of the first row slits SLT1 completely. The filler FIL may have a second length L2 from the end 710a of the folding portion 710. The second length L2 may be equal or substantially equal to the length of each of the first row slits SLT1 in the second direction DR2.

In the display device 10 according to this embodiment, the filler FIL might not be disposed in row slits other than the first row slits SLT1. For example, the filler FIL might not be disposed in the second to fourth row slits SLT2 to SLT4. In the display device 10 according to this embodiment, the filler FIL is not disposed in the row slits other than the first row slits SLT1, thereby reducing folding stress when the display device 10 is folded or being folded.

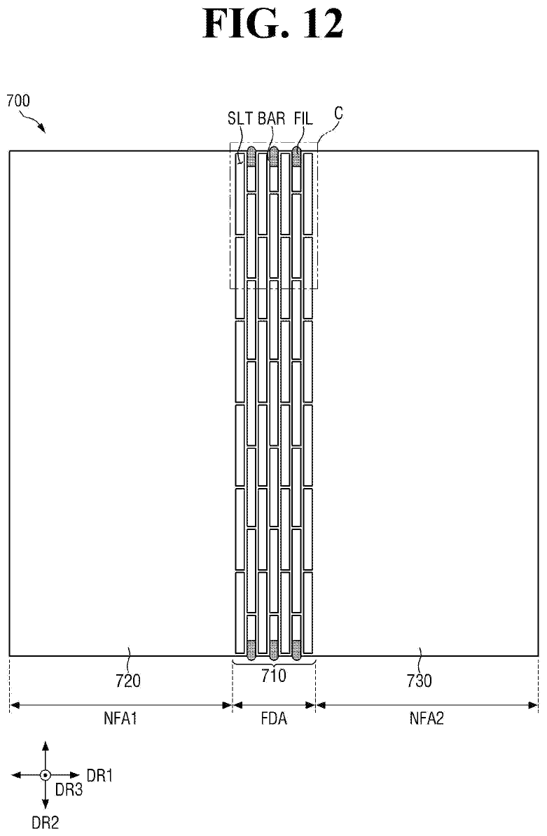

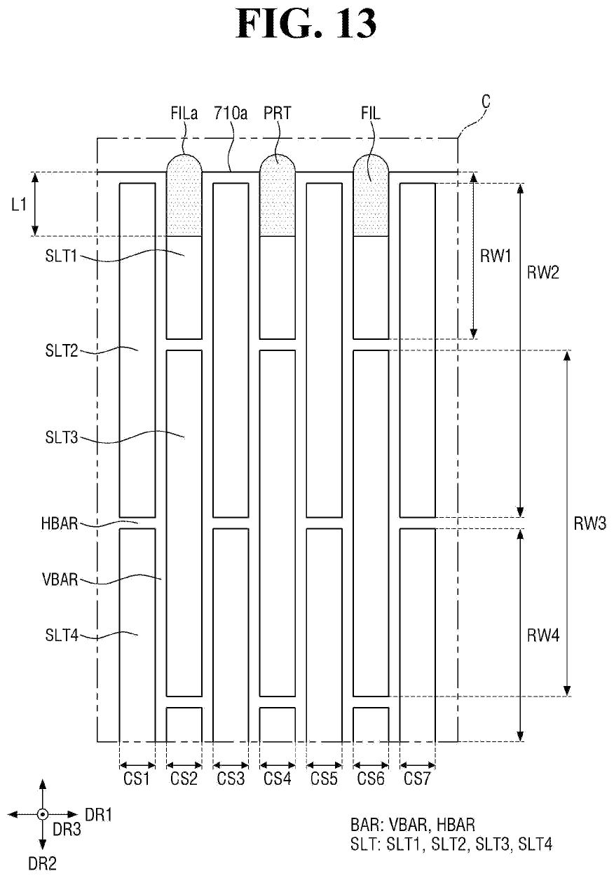

FIG. 12 is a plan view showing a panel support member according to an embodiment of the present invention. FIG. 13 is an enlarged view of area C of FIG. 12.

A display device 10 according to the embodiment of FIGS. 12 and 13 is different from the display device 10 according to the embodiment of FIGS. 7, 10 and the like in that ends FILa of a filler FIL protrude from the end 710a of the folding portion 710.

For example, the ends FILa of the filler FIL may protrude from the end 710a of the folding portion 710 in the second direction DR2. For example, the filler FIL may include protrusions PRT that protrude beyond the end 710a of the folding portion 710.

In embodiments of the present invention, the ends FILa of the filler FIL, i.e., the protrusions PRT may have a rounded shape. As described above, in the display device 10 according to this embodiment, since the modulus of the filler FIL is relatively low, the ends FILa of the filler FIL may have a rounded shape due to surface tension. It is, however, to be understood that the present invention is not limited thereto.

Although all of the ends FILa of the filler FIL that are disposed in the first row slits SLT1 protrude from the end 710a of the folding portion 710 in the drawings, the present invention is not limited thereto. For example, only some of the ends FILa of the filler FIL that are disposed in the first row slits SLT1 may protrude beyond the end 710a of the folding portion 710. In an embodiment of the present invention, only some of the ends FILa of the filler FIL that are disposed in the first row slits SLT1 may protrude beyond the end 710a of the folding portion 710, and other ends FILa of the filler FIL that are disposed in the first row slits SLT1 may be coplanar with the end 710a of the folding portion 710.

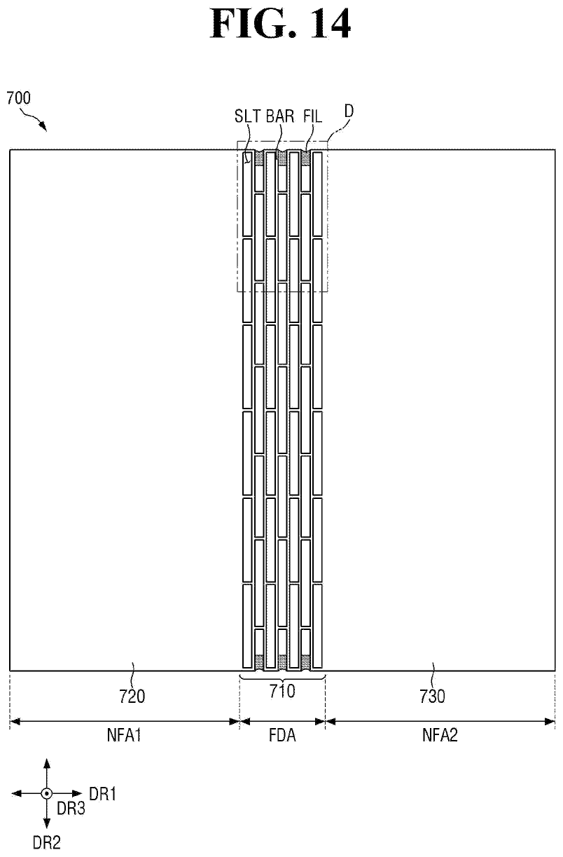

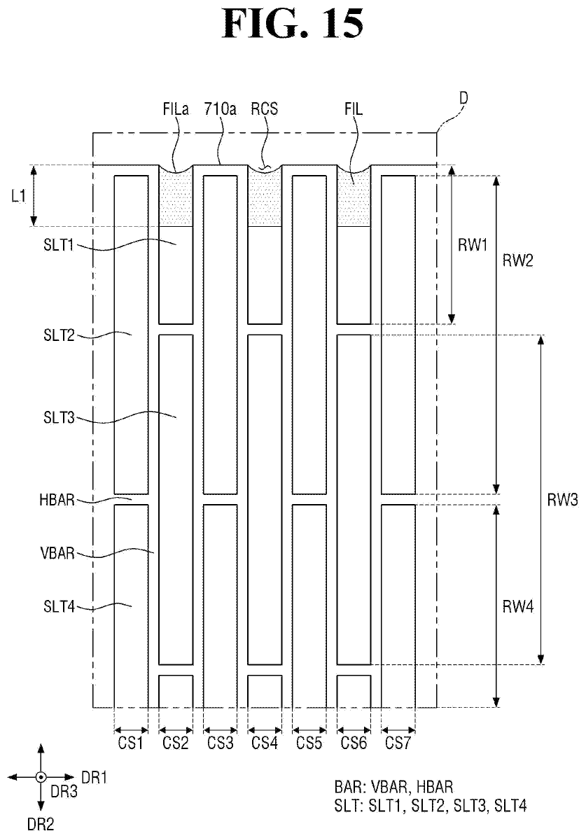

FIG. 14 is a plan view illustrating a panel support member according to an embodiment of the present invention. FIG. 15 is an enlarged view of area D of FIG. 14.

A display device 10 according to the embodiment of FIGS. 14 and 15 is different from the display device 10 according to the embodiment of FIGS. 7, 10, 12, 12 and the like in that ends FILa of a filler FIL is recessed from the end 710a of the folding portion 710.

For example, the ends FILa of the filler FIL may be recessed away from the end 710a of the folding portion 710 and inward of the folding portion 710. For example, the filler FIL may include recesses RCS that are recessed from the end 710a of the folding portion 710. In the display device 10 according to this embodiment, if the amount of the filler FIL is small or the adhesion between the filler FIL and a plurality of bars BAR is high, the recesses RCS may be formed. It should be understood, however, that the present invention is not limited thereto. In embodiments of the present invention, the ends FILa of the filler FIL, i.e., the recesses RCS may have a rounded shape, but the present invention is not limited thereto.

Although all of the ends FILa of the filler FIL that are disposed in the first row slits SLT1 are recessed from the end 710a of the folding portion 710 in the drawings, the present invention is not limited thereto. For example, only some of the ends FILa of the filler FIL that are disposed in the first row slits SLT1 may be recessed from the end 710a of the folding portion 710.

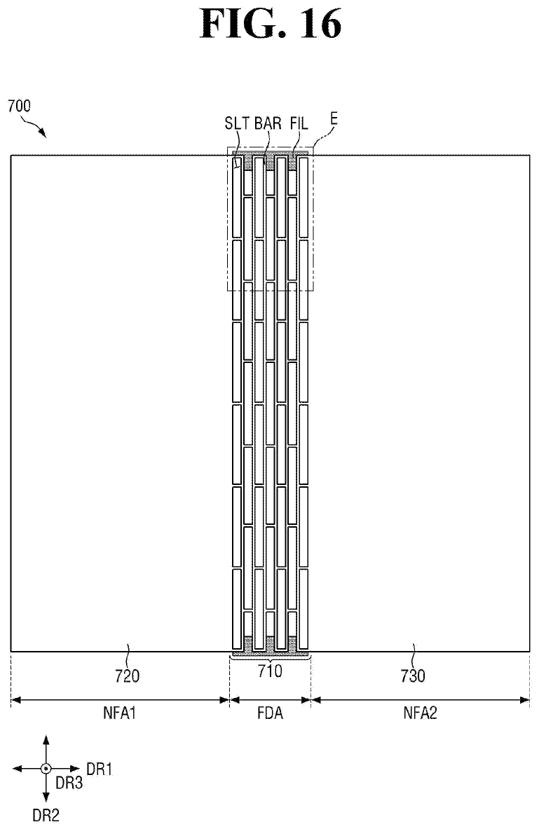

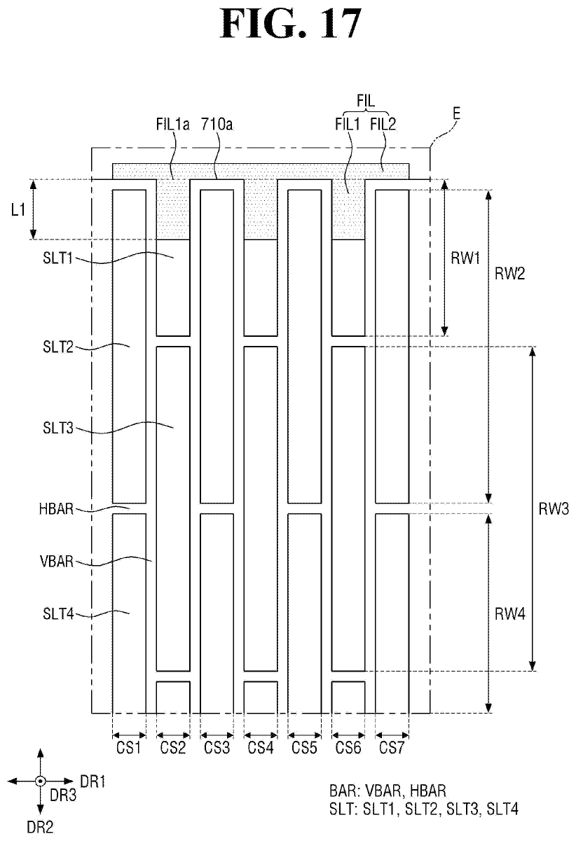

FIG. 16 is a plan view illustrating a panel support member according to an embodiment of the present invention. FIG. 17 is an enlarged view of area E of FIG. 16.

A display device 10 according to the embodiment of FIGS. 16 and 17 is different from the display device 10 according to the embodiment of FIGS. 7, 10, 12, 14 and the like in that a filler FIL includes first portions FIL1 and a second portion FIL2.

For example, the filler FIL may include first portions FIL1 and a second portion FIL2. In the following description, the first portions FIL1 and the second portion FIL2 are separately described for convenience of illustration, but the first portions FIL1 and the second portion FIL2 may be physically connected with each other as one body.

The first portions FIL1 may be disposed in a plurality of slits SLT. For example, the first portions FIL1 may be disposed between a plurality of bars BAR in the first direction DR1. Ends FIL1a of the first portions FIL1 may be positioned on the same line as the end 710a of the folding portion 710 in the second direction DR2.

The second portion FIL2 may be located on the outer side of the folding portion 710. For example, the second portion FIL2 may be disposed more to the outside than the first slit row RW1 in the second direction DR2. The second portion FIL2 may be located more to the outside than a plurality of bars BAR and a plurality of slits SLT that are disposed in the first slit row RW1 in the second direction DR2. For example, the second portion FIL2 is disposed outside of the panel support member 700.

The second portion FIL2 may be extended in the first direction DR1. The second portion FIL2 may be in direct contact with the end 710a of the folding portion 710. For example, the second portion FIL2 may be in direct contact with the end 710a of the folding portion 710 in the first slit column CS1, the third slit column CS3, the fifth slit column CS5 and the seventh slit column CS7, and may be in direct contact with the first portions FIL1 in the second slit column CS2, the fourth slit column CS4, and the sixth slit column CS6.

As the display device 10 according to this embodiment further includes the second portion FIL2, it is possible to reduce stress that is applied to the folding portion 710.

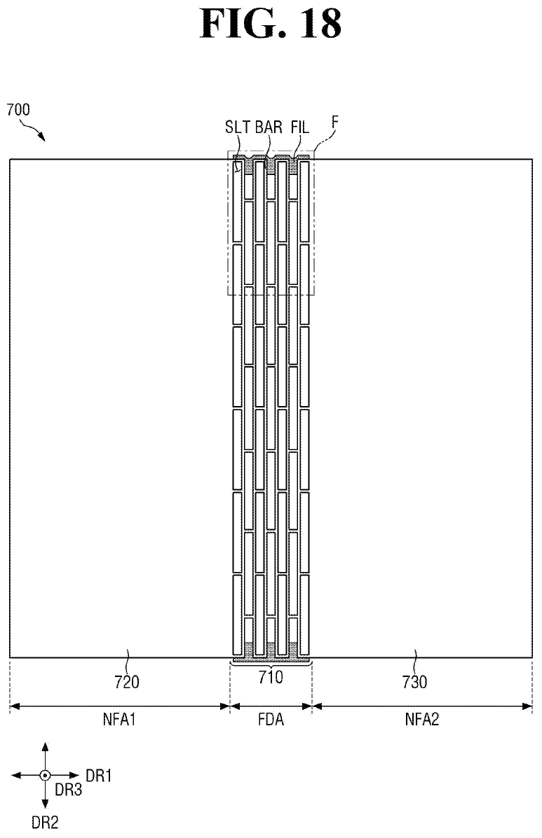

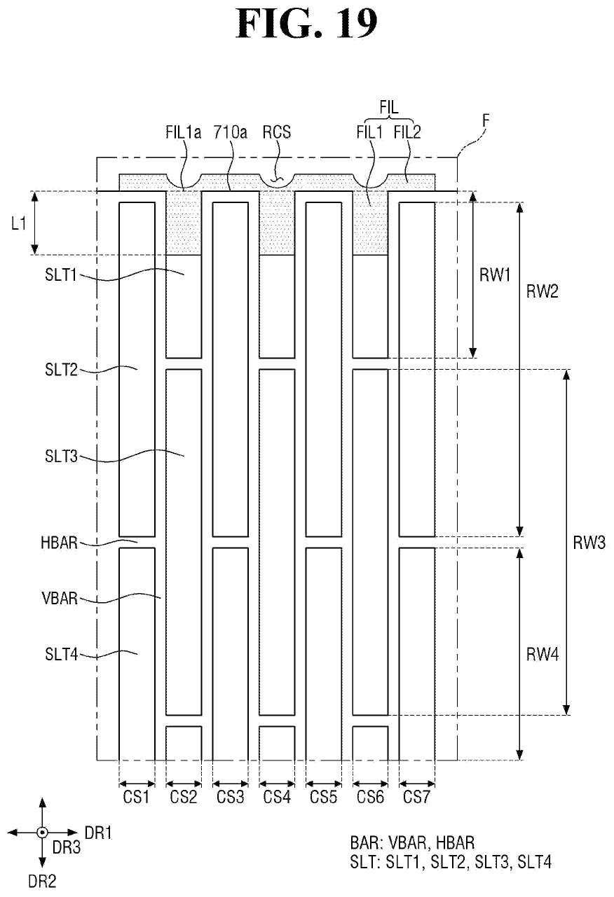

FIG. 18 is a plan view illustrating a panel support member according to an embodiment of the present invention. FIG. 19 is an enlarged view of area F of FIG. 18.

A display device 10 according to the embodiment of FIGS. 18 and 19 is different from the display device 10 according to the embodiment of FIG. 16 and the like in that a second portion FIL2 of a filler FIL includes recesses RCS.

For example, the second portion FIL2 may further include recesses RCS.

The recesses RCS may overlap with the first portions FIL1 in the second direction DR2. The recesses RCS may overlap with the first slits SLT1 that are disposed in the second slit column CS2, the fourth slit column CS4 and the sixth slit column CS6 in the second direction DR2.

In the display device 10 according to this embodiment, if the amount of the filler FIL is small or the adhesion between the filler FIL and a plurality of bars BAR is high, the recesses RCS may be formed. It should be understood, however, that the present invention is not limited thereto. In embodiments of the present invention, the recesses RCS may have a rounded shape, but the present invention is not limited thereto.

Although the recesses RCS are formed in all of the second slit column CS2, the fourth slit column CS4 and the sixth slit column CS6 in the drawings, the present invention is not limited thereto. For example, the recesses RCS may be formed in only some of the second slit column CS2, the fourth slit column CS4 and/or the sixth slit column CS6.

While the present invention has been described with reference to the embodiments thereof, it will be understood by those of ordinary skill in the art that various changes in form and detail may be made thereto without departing from the spirit and scope of the present invention.

What is claimed is:

1. A display device comprising:
a display panel comprising a folding area; and
a panel support layer disposed on the display panel and comprising a folding portion that overlaps the folding area,
wherein the panel support layer comprises:
one or more bars and one or more slits alternately arranged with each other in the folding portion; and
a filler disposed at least partially in the one or more slits, and
wherein the filler is disposed in first row slits among the one or more slits that are located at two ends of the folding portion.

2. The display device of claim 1, wherein the filler is disposed only partially in the first row slits.

3. The display device of claim 2, wherein a length of the filler is smaller than a length of the first row slits.

4. The display device of claim 2, wherein the filler is disposed adjacent to an end of the folding portion.

5. The display device of claim 4, wherein ends of the filler are flat surfaces.

6. The display device of claim 5, wherein the ends of the filler and the end of the folding portion are positioned on substantially a same plane.

7. The display device of claim 2, wherein the end of the folding portion of the panel support layer protrudes beyond an end of the display panel.

8. The display device of claim 7, wherein the end of the folding portion comprises a first region that protrudes beyond the end of the display panel,
wherein the first row slits at least partially overlap with the first region, and
wherein the filler is disposed only in the first region.

9. The display device of claim 8, wherein a length of the first region is equal to the length of the filler.

10. The display device of claim 1, wherein the filler is not disposed in row slits other than the first row slits.

11. The display device of claim 1, wherein a modulus of the filler is equal to or less than about 15 MPa.

12. The display device of claim 1,
wherein the filler comprises:
first portions disposed in the first row slits; and
a second portion disposed outside of the first row slits, and
wherein the second portion overlaps the one or more slits and the one or more bars.

13. The display device of claim 12, wherein the second portion comprises recesses that overlap with the one or more slits.

14. The display device of claim 1, wherein the ends of the filler comprise protrusions that protrude beyond the end of the folding portion.

15. The display device of claim 14, wherein the ends of the filler have a rounded shape.

16. The display device of claim 1, wherein the first row slits comprise a plurality of slits arranged in a first direction different from a direction in which the folding portion is extended, and
wherein the filler is disposed in all of the plurality of slits of the first row slits.

17. The display device of claim 16, wherein first ends of the filler that are disposed in the plurality of slits protrude beyond an end of the folding portion and have a rounded surface, and
wherein second ends, opposite to the first ends, of the filler that are disposed in the plurality of slits have a flat surface.

18. The display device of claim 1, wherein the ends of the filler comprise recesses that are recessed from the end of the folding portion.

19. The display device of claim 1, wherein the end of the folding portion comprises portions where no bar is disposed.

20. The display device of claim 1, wherein the filler is disposed entirely in the first row slits.
